(19) United States
(12) Patent Application Publication
(10) Pub. No.: US 2026/0239537 A1
(43) Pub. Date: Aug. 13, 2026

(54) Notch Design and Rocking Fixture for Board Stacking

(71) Applicant: Apple Inc., Cupertino, CA (US)

(72) Inventors: Huili Xu, San Jose, CA (US); ZhiQiang Zeng, Guangdong (CN); Gikku J. George, Campbell, CA (US); Micheal D. Teschler, Sunnyvale, CA (US); Yangqing Chen, Guangdong (CN); Abhishek Choudhury, San Jose, CA (US); Yaodong Wang, San Jose, CA (US); Henry H. Yang, San Jose, CA (US); Isaias Daguio, Shanghai (CN); Shing T. Tse, San Francisco, CA (US); James W. Bilanski, Palo Alto, CA (US); Dong Li, Guangdong (CN); Keh Shyong Tew, Zhengzhou (CN); Anthony Liu, San Jose, CA (US)

(21) Appl. No.: 19/079,145

(22) Filed: Mar. 13, 2025

(30) Foreign Application Priority Data
Feb. 13, 2025 (CN) 202510164390.4

(51) Int. Cl. H05K 1/14

(52) U.S. Cl. CPC H05K 1/144; H05K 2201/042; H05K 2201/09063; H05K 2201/09172; H05K 2201/10378

(57) ABSTRACT

Stacked circuit board structures, methods of assembly, and an alignment fixture are described. In an embodiment, a stacked circuit board structure includes bottom and top circuit boards with aligned alignment notches and alignment holes. Alignment of the stacked circuit boards may be achieved with an alignment fixture including rocking pins that mate with the alignment notches and alignment holes.

### RELATED APPLICATIONS

This application claims the benefit of priority Chinese Patent Application No. 202510164390.4, filed Feb. 13, 2025.

### BACKGROUND

### Field

Embodiments described herein relate to electronic packaging, and more particularly to printed circuit board assembly.

### Background Information

The main logic board (MLB) is a common part in almost all of the consumer electronics. As the trend continues to make products smaller, there is a drive for the integration of smaller and thinner dies, packages and components. There is also a competing drive for the integration of a higher density of components, leading to restrictions on areas, heights, or shapes. Assembly of current MLBs may include a stacking process to bond one or more boards and interposers together. This can be conventionally accomplished by forming alignment holes through a thickness of the one or more boards and interposers, and aligning the alignment holes with corresponding alignment pins of an alignment fixture. This may be followed by a thermal process for example to reflow solder joints to electrically and physically connect the stacked structure.

### SUMMARY

Embodiments describe stacked circuit board structures, methods of assembly and an alignment fixture for assembling the stacked circuit board structures. In an embodiment, an alignment fixture includes a support substrate, a first rocking pin in the support substrate, and a second rocking pin in the support substrate. Both of the first and second rocking pins can be laterally tiltable. The first rocking pin may include a first nub protruding from the back side of the support substrate and a first alignment pin protruding from a top side of the support substrate. Similarly, the second rocking pin may include a second nub protruding from the back side of the support substrate and a second alignment pin protruding from the top side of the support substrate.

In an embodiment, a method of stacking circuit boards includes placing a bottom circuit board onto an alignment fixture of which a first rocking pin extends through a bottom alignment hole of the bottom circuit board and a second rocking pin is adjacent to a bottom alignment notch of the bottom circuit board. A top circuit board is then placed over the bottom circuit board such that the first rocking pin extends through a top alignment hole of the top circuit board and the second rocking pin is adjacent to a top alignment notch of the top circuit board. A force can then be applied to the first rocking pin and the second rocking pin to align the top alignment hole with the bottom alignment hole and to align the top alignment notch with the bottom alignment notch.

In an embodiment, a resulting stacked circuit board structure includes a bottom circuit board including a bottom alignment notch and a bottom alignment hole, and a top circuit board over the bottom circuit board, the top circuit board including a top alignment notch aligned with the bottom alignment notch and a top alignment hole aligned with the bottom alignment hole.

### BRIEF DESCRIPTION OF THE DRAWINGS

FIG. 1 is an exploded isometric view illustration of a stacked circuit board structure in accordance with an embodiment.

FIG. 2 is a top plan view illustration of an interposer aligned with a bottom circuit board in accordance with an embodiment.

FIG. 3 is a close-up top plan view illustration of an alignment notch in accordance with an embodiment.

FIG. 4 is a schematic cross-sectional side view illustration of a stacked circuit board structure on an alignment fixture prior to alignment with rocking pins in accordance with an embodiment.

FIG. 5 is a schematic cross-sectional side view illustration of a stacked circuit board on an alignment fixture after alignment with rocking pins in accordance with an embodiment.

### DETAILED DESCRIPTION

Embodiments describe stacked circuit board structures, methods of assembly and an alignment fixture for assembling the stacked circuit board structures. In accordance with embodiment, the stacked structures can include a bottom circuit board including a bottom alignment notch and a bottom alignment hole, and a top circuit board over the bottom circuit board, the top circuit board including a second notch aligned with the bottom notch and a top alignment hole aligned with the bottom alignment hole. The circuit boards can be aligned by applying a force to rocking pins within an alignment fixture that engage with the alignment notches and alignment holes.

In one aspect, it has been observed that conventional circuit board stacking and alignment is accomplished by forming at least two alignment holes within the circuit boards, which reduces the available area for component placement and electrical routing. In accordance with embodiments, alignment notches are formed along edges of the stacked boards (e.g., printed circuit boards, interposers, etc.) to replace one or more of the alignment holes. An alignment fixture including rocking pins can be used for assembly in which the rocking pins engage with the notches for precise self-alignment, which may additionally provide for reduced pad-to-pad pitch tolerances for the landing pads between the stacked boards and reduced risk of misalignment-induced failures such as solder-bridging.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over”, or “on” another layer or bonded “to” or in “contact” with another layer may be directly in contact with the other layer or may have one or more intervening layers. One layer “between” layers may be directly in contact with the layers or may have one or more intervening layers.

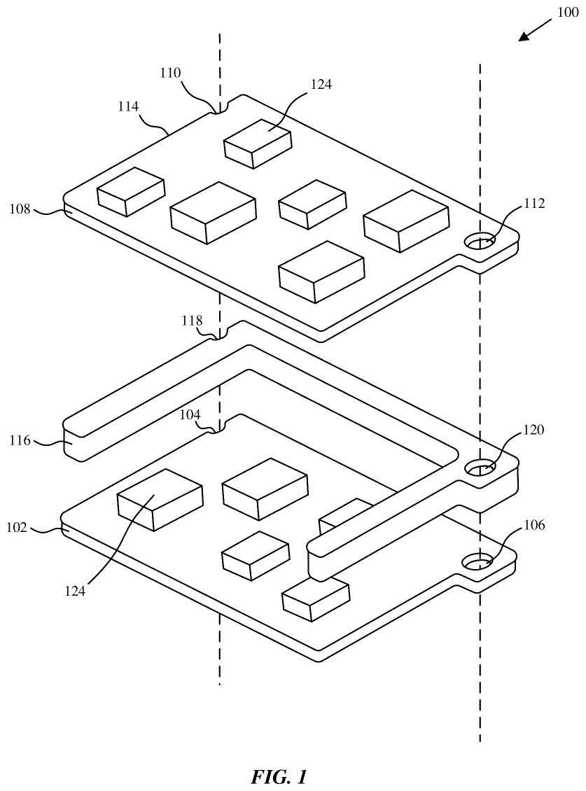

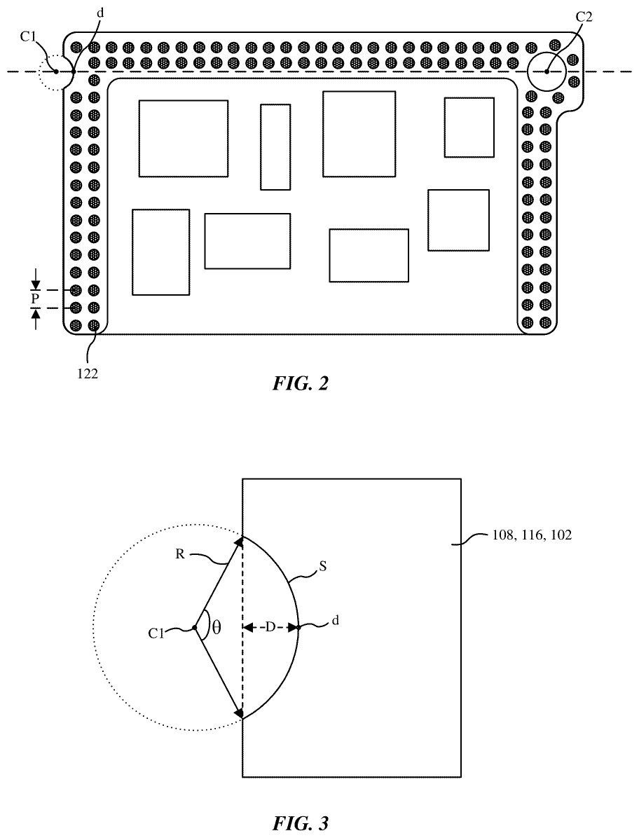

Referring now to FIG. 1 an exploded isometric view illustration is provided of a stacked circuit board structure 100 in accordance with an embodiment. FIG. 2 is a top plan view illustration of an interposer aligned with a bottom circuit board in accordance with an embodiment. FIG. 3 is a close-up top plan view illustration of an alignment notch in accordance with an embodiment. In interest of clarity and conciseness, FIGS. 1-3 are discussed concurrently.

As shown, the stacked circuit board structure 100 may include a bottom circuit board 102 including a bottom alignment notch 104 and a bottom alignment hole 106, and a top circuit board 108 over the bottom circuit board 102. The top circuit board 108 may additionally include a top alignment notch 110 aligned with the bottom alignment notch 104 and a top alignment hole 112 that is aligned with the bottom alignment hole 106. The top alignment notch 110 can be located along an edge 114 of the top circuit board 108 that is laterally opposite the top alignment hole 112, though this is not necessarily required. The other boards may be similarly arranged.

In accordance with embodiments, the alignment notches may replace the various alignment holes found in conventional stacked circuit board arrangements. Fine alignment may be achieved with alignment notches, though at least one alignment hole may be included in each board for coarse alignment with the alignment fixture.

In accordance with embodiments an interposer 116 is bonded to the bottom circuit board 102, and the top circuit board 108 is bonded to the interposer 116. Similarly, the interposer can include an intermediate alignment notch 118 and an intermediate alignment hole 120. When aligned and bonded together, the top alignment notch 110 is additionally aligned with the intermediate alignment notch 118 and bottom alignment notch 104, and the top alignment hole 112 is aligned with the intermediate alignment hole 120 and the bottom alignment hole. In some embodiments the top alignment notch, 110, intermediate alignment notch 118 and bottom alignment notch 104 are all characterized by a same radius (or other shape), and lateral surfaces(S) thereof (see FIG. 3) are vertically aligned. Similarly lateral surfaces of the alignment holes can be vertically aligned.

In accordance with embodiments the interposer 116 can be bonded to the bottom circuit board 102 using a suitable electrical connection, such as with a plurality of solder joints. Similarly, the top circuit board can be bonded to the interposer 116 (or directly to the bottom circuit board) with a plurality of solder joints. The self-alignment assembly method in accordance with embodiments may facilitate fine alignment, as well as fine landing pad 122 pitch (P) as shown in FIG. 2. For example, the top side of the interposer 116 may have an arrangement of landing pads with a minimum pitch (P) of less than 180 microns, such as less than 150 microns, or less than 125 microns. The bottom side of the top circuit board 108 may have a similar landing pad layout, where the landing pads are bonded together with solder joints, where the solder can be reflowed after fine alignment. The bottom circuit board and interposer may be similarly joined with similar landing pad layouts and solder joints.

The alignment notches in accordance with embodiments may assume a variety of shapes including being characterized by a radius (e.g., semi-circular, though may have a 180 degree arc angle or less), elliptical, oblong, U-shaped, etc. In a particular embodiment the notches are characterized by a radius. In order effectively mate with the rocking pin (which may be cylindrical), the notches may be characterized by at least a 90 degree arc angle (θ). As shown in FIGS. 2-3, the alignment notches can extend a lateral depth (D) into the respective circuit boards. The lateral depth may be at least 25% of the radius in some embodiments in order to effectively mate with the rocking pins. Furthermore, center points (C1) of the radius of the alignment notches, a point of maximum depth (d) of the alignment notches, and center points (C2) of the alignment holes within the corresponding holes may be linearly aligned, as shown by the dashed line in FIG. 2. Such orientation may allow for active engagement with the rocking pins and mitigated slipping.

The bottom circuit board 102 in accordance with embodiments may be rigid or flexible, and may be formed of a variety of suitable printed circuit board (PCB) materials including FR4, prepreg, polyimide, etc. The electronic components 124 mounted thereon in accordance with embodiments can be dies ranging from system-on-chip (SOC) to memory, passive components (resistors, capacitors, inductors, etc.), micro-electromechanical systems (MEMS), sensors, etc. A variety of configurations of different electronic components is understood.

The top circuit board 108 is also illustrated including a plurality of electronic components 124 mounted on a top side thereof. Additional electronic components 124 may also be optionally mounted on the bottom side of the top circuit board 108 and facing the bottom circuit board. Similar to the bottom circuit board 102, the top circuit board 108 may be rigid or flexible, and formed of the same materials described with regard to the bottom circuit board 102. Similarly, electronic components 124 may be selected from the same electronic components in accordance with embodiments can be dies ranging from system-on-chip (SOC) to memory, passive components (resistors, capacitors, inductors, etc.), micro-electromechanical systems (MEMS), sensors, etc. In a specific implementation the top circuit board 108 is a rigid wireless access point (AP) board, while the bottom circuit board 102 is a rigid or flexible radio frequency (RF) board.

The interposer 116 may optionally be formed of a similar material as the circuit boards, such as FR4 (a woven fiberglass impregnated with resin) for example. Thus, the interposer 116 may also be considered a routing substrate or board. The interposer 116 may function to provide electrical routing between the top and bottom circuit boards, and/or the interposer 116 may perform a primarily mechanical function. Even when performing a primarily mechanical function, such as a spacer or thermal coefficient matching, the interposer 116 may be formed of typical routing substrate material, such as FR4 board. Interposer 116 may additionally be formed of alternative materials including silicon, organics (e.g. polyimide), etc.

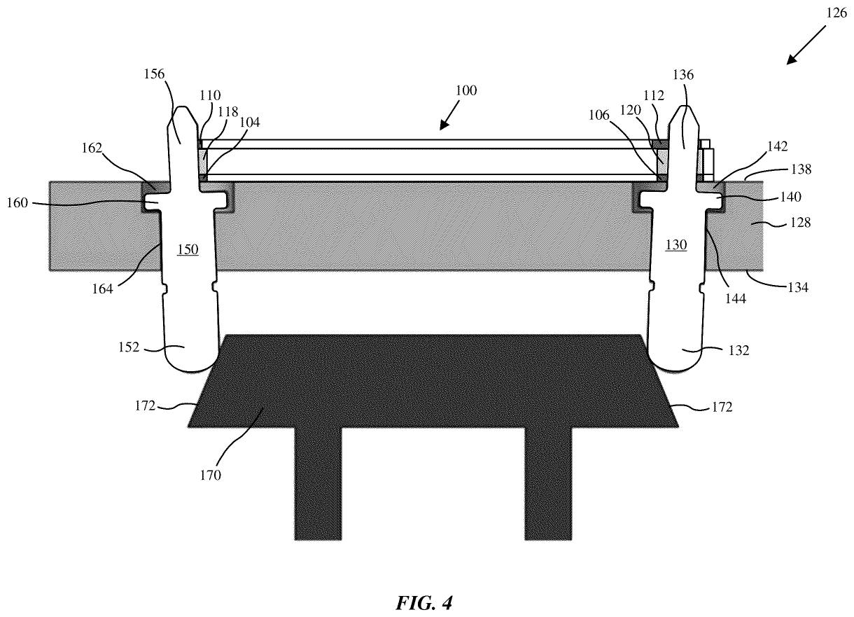

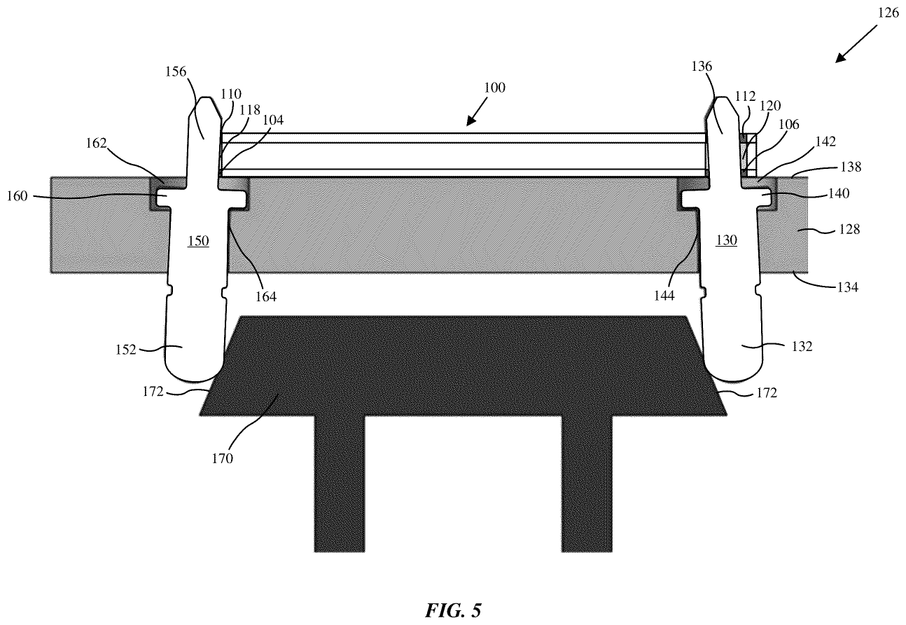

Referring now to FIGS. 4-5, FIG. 4 is a schematic cross-sectional side view illustration of a stacked circuit board structure on an alignment fixture prior to alignment with rocking pins in accordance with an embodiment, FIG. 5 is a schematic cross-sectional side view illustration of a stacked circuit board on an alignment fixture after alignment with rocking pins in accordance with an embodiment. As shown, the alignment fixture 126 can include a support substrate 128, a first rocking pin 130 in the support substrate 128, the first rocking pin 130 including a first nub 132 protruding from a back side 134 of the support substrate 128 and a first alignment pin 136 protruding from a top side 138 of the support substrate 128. The first rocking pin 130 is laterally tiltable within the support substrate 128. A top flange 140 of the first rocking pin 130 may rest inside an upper cavity 142 in the support substrate, with a bulk portion of the first rocking pin 130 and first nub 132 protruding extending out of a through hole 144 of smaller size (diameter) than the upper cavity 142. The through hole 144 may have a slightly larger width (diameter) than a bulk of the first rocking pin 130 to allow for tilting motion of the first rocking pin.

The alignment fixture 126 can additionally include a second rocking pin 150 arranged in the support substrate 128 similarly as the first rocking pin with a second nub 152 protruding from a back side 134 of the support substrate 128 and a second alignment pin 156 protruding from a top side 138 of the support substrate 128. The second rocking pin 150 is laterally tiltable within the support substrate 128. A top flange 160 of the second rocking pin 150 may rest inside an upper cavity 162 in the support substrate, with a bulk portion of the second rocking pin 150 and second nub 152 protruding extending out of a through hole 164 of smaller size (diameter) than the upper cavity 162. The through hole 164 may have a slightly larger width (diameter) than a bulk of the second rocking pin 150 to allow for tilting motion of the second rocking pin. It is to be appreciated that while two rocking pins are illustrated that more may be included.

The alignment fixture 126 may additionally include a platen 170 adjacent to the back side 134 of the support substrate 128, where the platen 170 is vertically movable toward the back side 134 of the support substrate 128 to engage with the first nub 132 and the second nub 152, and tilt the first nub 132 and second nub 152 away from one another and cause the first alignment pin 136 and the second alignment pin 136 to tilt toward one another. The first alignment pin 136 and second alignment pin 156 may have a shape that mates with the alignment notches in the boards. For example, the alignment pins may both be cylindrical to mate with alignment notches that are characterized by a radius. As shown, the platen 170 may have tapered side surfaces 172 that slide along the rounded nubs of the rocking pins to tilt the corresponding alignment pins of the rocking pins toward the stacked board arrangements.

The alignment fixture 126 in accordance with embodiments may be utilized to stack and bond multiple boards simultaneously or sequentially. For example, in some embodiments the interposer 116 can be first stacked onto the bottom circuit board 102 using the alignment fixture 126 followed by solder reflow to bond the interposer 116 to the bottom circuit board 102. The reflow operation may be performed within the alignment fixture 126 or elsewhere. The stacked interposer 116 and bottom circuit board 102 can then be re-introduced to the alignment fixture 126 followed by placement of the top circuit board 108, alignment and reflow. In some embodiments an interposer is not used, or possibly a plurality of side-by-side local interposers is utilized.

In an embodiment a method of stacking circuit boards includes placing a bottom circuit board 102 onto an alignment fixture 126 of which a first rocking pin 130 extends through a bottom alignment hole 106 of the bottom circuit board 102 and a second rocking pin 150 is adjacent to a bottom alignment notch 104 of the bottom circuit board 102. A top circuit board 108 is then placed over the bottom circuit board 102 such that the first rocking pin 130 extends through a top alignment hole 112 of the top circuit board 108 and the second rocking pin 150 is adjacent to a top alignment notch 110 of the top circuit board 108. A force can then be applied to the first rocking pin 130 and second rocking pin 150 to align the top alignment hole 112 with the bottom alignment hole 106 and to align the top alignment notch 110 with the bottom alignment notch 104. In some embodiments an interposer 116 is already bonded to the bottom circuit board 102, and placing the top circuit board 108 over the bottom circuit board 102 includes placing the top circuit board 108 onto the interposer 116. In accordance with embodiments, the force applied to the rocking pins is transferred as compressive force to the stacked boards, causing the boards to shift and align the various alignment notches and alignment holes. As described with regard to FIG. 2 a center point C1 of the alignment notches, a point of maximum lateral depth D of the alignment notches, and a center point C2 of the alignment holes are linearly arranged. Following alignment, in an embodiment a plurality of solder bumps are reflowed to bond the top circuit board 102 to the interposer 116.

It is to be appreciated that while the above description and illustrations are made with regard to a single alignment hole and single alignment notch configuration that embodiments are not so limited. For example, similar alignment can be achieved with two laterally opposite alignment notches. Furthermore, additional alignment notches may be included.

In utilizing the various aspects of the embodiments, it would become apparent to one skilled in the art that combinations or variations of the above embodiments are possible for forming a stacked circuit board structure. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A stacked circuit board structure comprising:
a bottom circuit board including a bottom alignment notch and a bottom alignment hole; and
a top circuit board over the bottom circuit board, the top circuit board including a top alignment notch aligned with the bottom alignment notch and a top alignment hole aligned with the bottom alignment hole.

2. The stacked circuit board structure of claim 1, wherein the top alignment notch is located in an edge of the top circuit board that is laterally opposite the top alignment hole.

3. The stacked circuit board structure of claim 1, wherein the top alignment notch is characterized by a radius.

4. The stacked circuit board structure of claim 3, wherein the top alignment notch is characterized by at least a 90 degree arc.

5. The stacked circuit board structure of claim 3, wherein the top alignment notch extends a lateral depth into the top circuit board, wherein the lateral depth is at least 25% of the radius.

6. The stacked circuit board structure of claim 5, wherein a center point of the radius of the top alignment notch, a point of maximum lateral depth of the top alignment notch, and a center point of the top alignment hole are linearly aligned.

7. The stacked circuit board structure of claim 1, further comprising an interposer bonded to the bottom circuit board, the interposer including an intermediate alignment notch and an intermediate alignment hole, wherein the top circuit board is bonded to the interposer, the top alignment notch is aligned with the intermediate alignment notch, and the top align hole is aligned with the intermediate alignment hole.

8. The stacked circuit board structure of claim 7, wherein the top alignment notch, the intermediate alignment notch, and the bottom alignment notch are all characterized by a same radius, and lateral surfaces of the top alignment notch, the intermediate alignment notch, and the bottom alignment notch are vertically aligned.

9. The stacked circuit board structure of claim 7, wherein the top circuit board is bonded to the interposer with a plurality of solder joints.

10. The stacked circuit board structure of claim 9, wherein the plurality of solder joints is bonded to a plurality of landing pads of the interposer, the plurality of landing pads having a minimum pitch of less than 180 microns.

11. The stacked circuit board structure of claim 1, wherein the top circuit board contains no additional alignment holes.

12. A method of stacking circuit boards comprising:
placing a bottom circuit board onto an alignment fixture of which a first rocking pin extends through a bottom alignment hole of the bottom circuit board and a second rocking pin is adjacent to a bottom alignment notch of the bottom circuit board;
placing a top circuit board over the bottom circuit board such that the first rocking pin extends through a top alignment hole of the top circuit board and the second rocking pin is adjacent to a top alignment notch of the top circuit board; and
applying a force to the first rocking pin and the second rocking pin to align the top alignment hole with the bottom alignment hole and to align the top alignment notch with the bottom alignment notch.

13. The method of claim 12, further comprising an interposer bonded to the bottom circuit board, wherein placing the top circuit board over the bottom circuit board comprises placing the top circuit board onto the interposer.

14. The method of claim 13, further comprising reflowing a plurality of solder bumps to bond the top circuit board to the interposer after applying the force to the first rocking pin and the second rocking pin.

15. The method of claim 12, wherein the first rocking pin and the second rocking pin both transfer compressive force to the top circuit board and the bottom circuit board.

16. The method of claim 15, wherein a center point of a radius of the top alignment notch, a point of maximum lateral depth of the top alignment notch, and a center point of the top alignment hole are linearly aligned.

17. An alignment fixture comprising:
a support substrate;
a first rocking pin in the support substrate, the first rocking pin including a first nub protruding from a back side of the support substrate and a first alignment pin protruding from a top side of the support substrate, the first rocking pin laterally tiltable; and
a second rocking pin in the support substrate, the second rocking pin including second nub protruding from the back side of the support substrate and a second alignment pin protruding from the top side of the support substrate, the second rocking pin laterally tiltable.

18. The alignment fixture of claim 17, further comprising a platen adjacent the back side of the support substrate, wherein the platen is vertically movable toward the back side of the support substrate.

19. The alignment fixture of claim 18, wherein the platen is vertically movable toward the back side of the support substrate to engage with the first nub and the second nub, and tilt the first nub and second nub away from one another and cause the first alignment pin and the second alignment pin to tilt toward one another.

20. The alignment fixture of claim 19, wherein the first alignment pin and the second alignment pin are both cylindrical.
